(19) United States
(12) Patent Application Publication
(10) Pub. No.: US 2022/0244298 A1
(43) Pub. Date: Aug. 4, 2022

(54) DEVICE AND METHOD FOR EXTRACTING ELECTRIC NETWORK FREQUENCY

(71) Applicant: Korea University Research and Business Foundation, Seoul (KR)

(72) Inventors: Ji Won YOON, Seoul (KR); Ji Hyuk JUNG, Seoul (KR); Youngbae JEON, Seongnam-si (KR)

(73) Assignee: Korea University Research and Business Foundation, Seoul (KR)

(21) Appl. No.: 17/587,084

(22) Filed: Jan. 28, 2022

(30) Foreign Application Priority Data
Jan. 29, 2021 (KR) 10-2021-0013501
Jan. 10, 2022 (KR) 10-2022-0003466

(51) Int. Cl. G01R 23/16; H02J 3/24

(52) U.S. Cl. CPC G01R 23/16; H02J 3/241

(57) ABSTRACT

Disclosed is a device and method for extracting electric network frequency (ENF). An ENF extraction device includes an electric conductor configured to receive an electromagnetic wave generated by an adjacent alternating current (AC) power source; a sampling device configured to sample an output signal of the electric conductor; and a processor configured to extract ENF based on an output signal of the sampling device.

### CROSS-REFERENCE TO RELATED APPLICATION(S)

This application claims the benefit under 35 USC § 119(a) of Korean Patent Application No. 10-2021-0013501 filed on Jan. 29, 2021 and Korean Patent Application No. 10-2022-0003466 filed on Jan. 10, 2022 in the Korean Intellectual Property Office, the entire disclosure of which is incorporated herein by reference for all purposes.

### BACKGROUND

### 1. Field

At least one example embodiment relates to a device and method for extracting electric network frequency (ENF).

### 2. Description of Related Art

Electric network frequency (ENF) refers to frequency of a power distribution networks (PDN) of a power grid. That is, the ENF may be considered to represent frequency of power or voltage supplied by the country. Through the ENF, the stability of power may be known and position information may be acquired.

ENF of a specific area needs to be continuously measured to estimate stability of power supply or position information. Here, a device called a frequency disturbance recorder (FDR) is used. However, price of the FDR is too expensive to purchase and use the FDR in an individual or a laboratory. Therefore, proposed herein is a method that may simply but efficiently extract ENF without using the FDR.

### SUMMARY

At least one example embodiment provides a method and apparatus that may simply extract electric network frequency (ENF) without using a frequency disturbance recorder (FDR).

An ENF extraction device according to an example embodiment includes an electric conductor configured to receive an electromagnetic wave generated by an adjacent alternating current (AC) power source; a sampling device configured to sample an output signal of the electric conductor; and a processor configured to extract ENF based on an output signal of the sampling device.

An ENF extraction method according to an example embodiment is performed by a computing device including at least a processor and includes receiving, by an electric conductor included in the computing device, an electromagnetic wave generated by an adjacent AC power source; sampling, by a sampling device included in the computing device, an output signal of the electric conductor; and extracting, by the processor, ENF based on an output signal of the sampling device.

An ENF extraction method and device according to some example embodiments may simply extract ENF at low cost without using an FDR.

The aforementioned features and effects of the disclosure will be apparent from the following detailed description related to the accompanying drawings and accordingly those skilled in the art to which the disclosure pertains may easily implement the technical spirit of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 illustrates a partial circuit diagram of an electric network frequency (ENF) extraction device according to an example embodiment;

FIG. 2 is a functional diagram of an ENF extraction device according to an example embodiment;

FIG. 3 is a graph showing a signal measured by a sound card of the ENF extraction device of FIG. 2;

FIG. 4 illustrates a spectrum of a signal measured by an auxiliary (AUX) cable of the ENF extraction device of FIG. 2;

FIG. 5 is a graph showing an ENF signal extracted from the spectrum measured in FIG. 4;

FIG. 6 is a graph showing an ENF signal extracted from a frequency disturbance recorder (FDR) and an ENF signal extracted according to an example embodiment;

FIG. 7 illustrates a row signal of light connected in time series in a video;

FIG. 8A illustrates an ENF signal extracted from an AUX cable and FIG. 8B illustrates an ENF signal extracted from a video; and

FIG. 9A illustrates normalized correlation coefficient (NCC) values over time and FIG. 9B illustrates a ground truth (GT) at a peak point.

### DETAILED DESCRIPTION

The aforementioned features and effects of the disclosure will be apparent from the following detailed description related to the accompanying drawings and accordingly those skilled in the art to which the disclosure pertains may easily implement the technical spirit of the disclosure.

Various modifications and/or alterations may be made to the disclosure and the disclosure may include various example embodiments. Therefore, some example embodiments are illustrated as examples in the drawings and described in detailed description. However, they are merely intended for the purpose of describing the example embodiments described herein and may be implemented in various forms. Therefore, the example embodiments are not construed as limited to the disclosure and should be understood to include all changes, equivalents, and replacements within the idea and the technical scope of the disclosure

Although terms of “first,” “second,” and the like are used to explain various components, the components are not limited to such terms. These terms are used only to distinguish one component from another component.

For example, a first component may be referred to as a second component, or similarly, the second component may be referred to as the first component within the scope of the present disclosure. As used herein, the term “and/or” includes any and all combinations of one or more of the associated listed items.

As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

Hereinafter, example embodiments are described with reference to the accompanying drawings. However, the scope of the disclosure is not limited to or restricted by the example embodiments. Like reference numerals illustrated in the respective drawings refer to like elements throughout.

In a power grid, solar energy, coal energy, and nuclear energy are converted to kinetic energy that rotates a turbine. A rotational speed of the turbine determines frequency of alternating current (AC) power. Electric network frequency (ENF) refers to frequency of AC power supplied by the power grid. Globally, the power grid uses the AC frequency of 50 or 60 hertz (Hz). AC voltage V may be represented as the following Equation 1.

$$V = Acos ( 2 π {f}_{e} t + ϕ ) \qquad [ Equation 1 ]$$

In Equation 1, A denotes an amplitude of a power source, Φ denotes a phase offset, and fₑ denotes ENF. To maintain stable power transport, fₑ needs to be constant. However, some fluctuations occur during fₑ in which a control unit of the power grid maintains balance between demand and supply for electrical energy. The range of changing frequency is very small compared to a base frequency (e.g., 60±0.019 Hz in case of power grids of the Republic of Korea). ENF is a standard for evaluating the stability of power grids in the United States. Therefore, a lot of efforts are required to collect ENF values of all power grids.

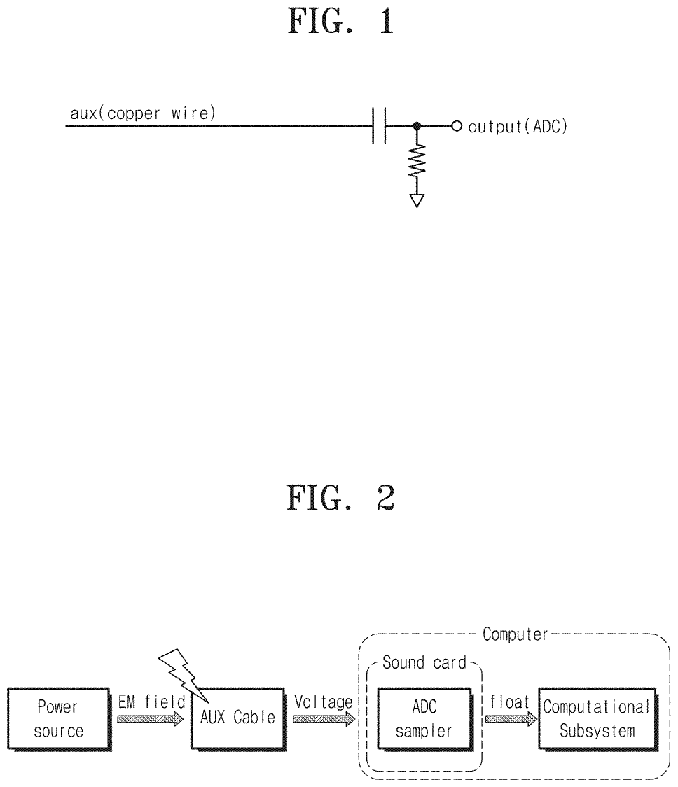

FIG. 1 is a partial circuit diagram of an ENF extraction device according to an example embodiment.

Referring to FIG. 1, the ENF extraction device may include an electric conductor configured to measure (or receive) an electromagnetic wave or an electromagnetic field generated from an AC power line adjacent to a place in which the ENF extraction device is present. According to Maxwell's equation, a change in current generates an electromagnetic field therearound. Therefore, the AC power may generate the electromagnetic field and the ENF may be extracted by measuring the generated electromagnetic field or electromagnetic wave.

The electric conductor serves as an antenna that receives (or measures) the electromagnetic wave or the electromagnetic field. The electric conductor may include a metal wire, such as an electric wire and a copper wire. Depending on example embodiments, the electric conductor may be implemented as an auxiliary (AUX) cable or an earphone with one end cut or open. To serve as the antenna that receives the electromagnetic wave, the AUX cable or the earphone needs to be made as an open circuit.

Although FIG. 1 illustrates that the antenna includes a capacitor connected between a reception end and an output end and a ground terminal connected between the capacitor and the output end as the AUX cable (, which may be implemented as an electric conductor, an electric wire, a copper wire, etc.) with one end open, the disclosure is not limited thereto. The antenna of the invention may be configured as the electric conductor to receive the surrounding electromagnetic field or electromagnetic wave.

FIG. 2 is a functional diagram of an ENF extraction device according to an example embodiment.

Referring to FIG. 2, the ENF extraction device includes a sampling device configured to sample an analog signal, for example, an electromagnetic wave received from an antenna implemented as an AUX cable and the like.

The sampling device may be implemented as an audio card or a sound card included in a computing device. However, the present invention is not limited thereto. Depending on example embodiments, the sampling device may be implemented as a general analog-to-digital converter (ADC) not the audio card or the sound card. The ENF extraction device may be implemented as the antenna configured to receive the electromagnetic wave, the sampling device configured to sample an output signal of the antenna, and a processor configured to extract ENF based on an output signal of the sampling device. The computing device may refer to a computer, a tablet PC, a personal computer, a desktop computer, a laptop computer, and a server, including at least a processor and/or memory. The output signal of the sampling device may be stored in the memory through a predetermined input/output (I/O) interface. The processor may extract the ENF using the output signal stored in the memory or received from the sampling device.

The sampling device may convert the output signal (e.g., a voltage signal) of the antenna to a digital signal having a predetermined sampling frequency and may output the same. Therefore, the sampling device that may be implemented as a sound card and the like may refer to a conversion device that converts, to a digital signal, an analog signal output from the antenna implementable as the AUX cable or the copper wire.

As described above, since an ENF extraction method using an electromagnetic wave simply requires locating the antenna that receives the electromagnetic wave near an AC source, the electromagnetic wave may be measured or the ENF may be extracted using a simple copper wire without using a complex circuit.

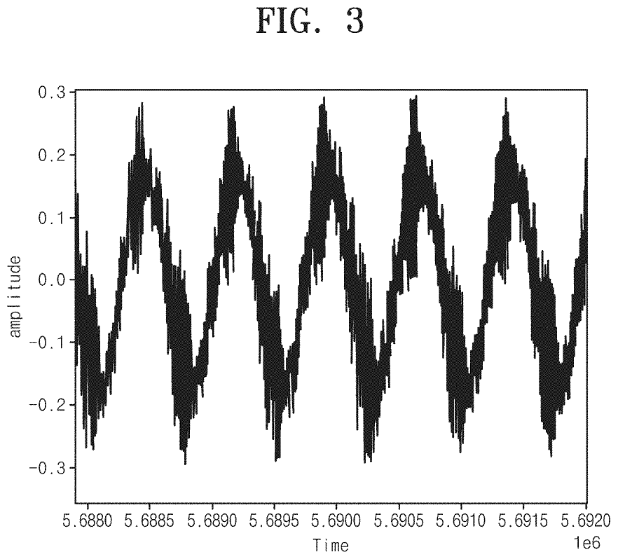

FIG. 3 is a graph showing a signal measured by a sound card of the ENF extraction device of FIG. 2. ENF may be extracted from a signal of FIG. 3 through the following method. An ENF extraction method may be performed by a processor included in the ENF extraction device.

A digital signal processor (DSP) of a frequency disturbance recorder (FDR) that converts a time domain to a frequency domain in real time and calculates ENF may be replaced with a simple python code. Therefore, the processor of the ENF extraction device may perform an operation of extracting the ENF according to the python code.

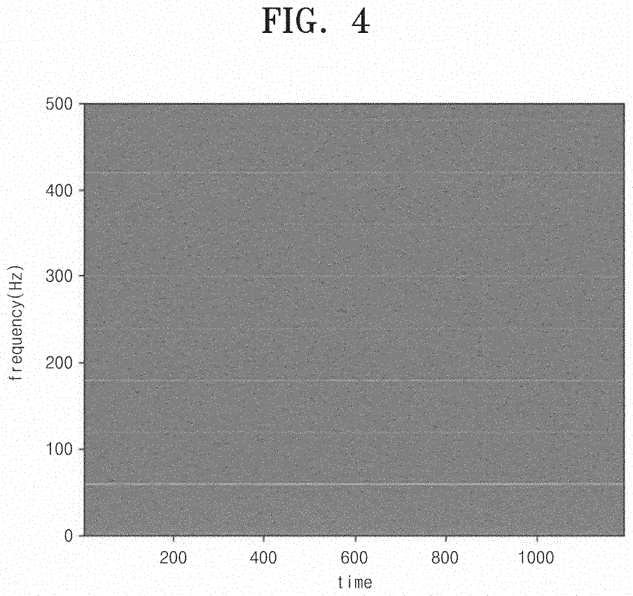

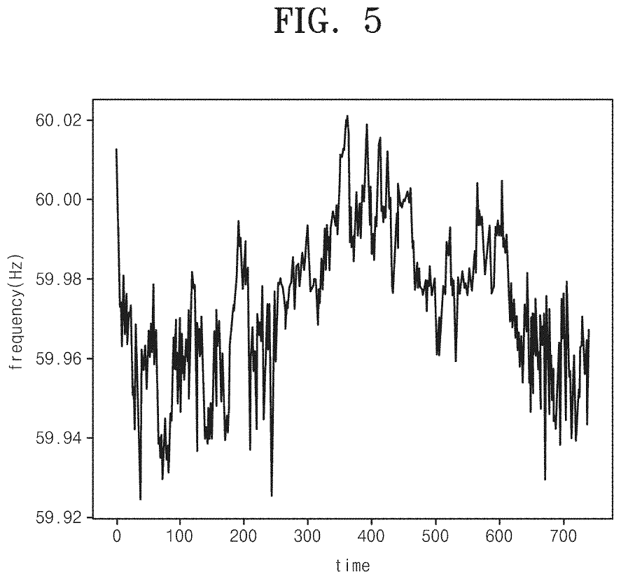

FIG. 4 illustrates a spectrum of a signal measured by an AUX cable of the ENF extraction device of FIG. 2, and FIG. 5 is a graph showing an ENF signal extracted from the spectrum measured in FIG. 4.

Referring to FIGS. 4 and 5, ENF may be extracted from a signal converted by a sound card of the ENF extraction device using a known method.

Initially, a voltage signal that is an output signal of the sound card may be converted to a frequency domain through a discrete short time Fourier transform (STFT). Also, a fine frequency value in a specific time may be determined using a quadratically interpolated fast Fourier transform (QIFFT). An STFT divides a time into frames and then converts a time-series signal to a frequency domain through a discrete Fourier transform (DFT). The DFT may be represented as the following Equation 2.

$$F [ k ] = {\sum }_{n = 0}^{N - 1} V [ n ] {e}^{- j \frac{2 π}{N} kn} \qquad [ Equation 2 ]$$

In Equation 2, k denotes a k^{th} frequency bin. The discrete STFT divides a signal into frames and then converts each frame to the frequency domain. Therefore, the discrete STFT may be represented as the following Equation 3.

$$F ( m , k ) = {\sum }_{n = 0}^{P} V [ n - mL ] {e}^{- j \frac{2 π}{N} kn} \qquad [ Equation 3 ]$$

In Equation 3, L denotes a hop size, P denotes a frame length, and F(m, k) denotes a k^{th} frequency amplitude of an m^{th} frame. For each frame m (time), frequency having a maximum amplitude near the ENF may be selected and a quadratic model may be fit to three data points around the selected frequency. This method is referred to as the QIFFT. It is possible to find a peak point of a quadratic function that passes through the three points. An x value of the peak point is an ENF value of the m^{th} frame.

The aforementioned ENF extraction may be performed by a processor of the ENF extraction device.

Hereinafter, an ENF signal extracted according to an example embodiment and an ENF extracted from an FDR are compared. To test for forensic applicability, a video is recorded with flashing light and a video recording time is estimated.

Performance Comparison With FDR

Comparing a normalized correlation coefficient (NCC) value to an ENF signal extracted from the FDR, it can be shown that an ENF signal captured from the ENF signal extracted according to an example embodiment is accurate. An NCC value between two signals may be evaluated according to the following Equation 4.

$$ρ ( {f}_{p} , {f}_{q} ) = \frac{{\sum }_{m = 0}^{M} [ {f}_{p} [ m ] - {u}_{p} ] [ {f}_{q} [ m ] - {u}_{q} ]}{\sqrt{{\sum }_{m = 0}^{M} {[ {f}_{p} [ m ] - {u}_{p} ]}^{2} {\sum }_{m = 0}^{M} {[ {f}_{p} [ m ] - {u}_{q} ]}^{2}}} \qquad [ Equation 4 ]$$

In Equation 4, fₚ and f_{q} denote signals with the same length, M denotes a time length of fₚ and f_{q}, and uₚ and u_{q} denote mean of fₚ and f_{q}. Using the FDR, an ENF signal was extracted for 120 minutes and an NCC value was compared with an ENF signal extracted from an AUX cable at the same time. A signal measured by the FDR was converted to an ENF signal of 0.1 sample/sec. In contrast, the ENF extraction device according to an example embodiment extracts an ENF signal at 1 sample per second.

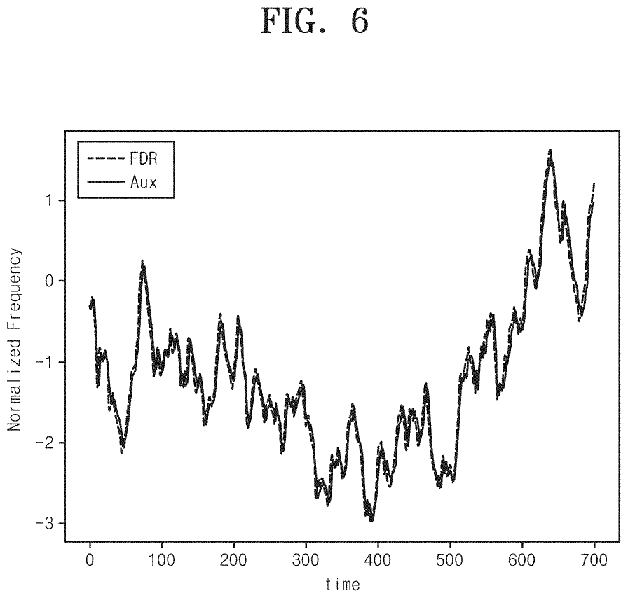

FIG. 6 is a graph showing an ENF signal extracted from an FDR and an ENF signal extracted according to an example embodiment.

Referring to FIG. 6, a signal extracted through the FDR and a signal extracted through an AUX cable have similar shapes, but have different time resolutions and frequency scales. A time scale resolution refers to a size of a frame. To compare two signals, an ENF signal extracted from the FDR was down-sampled and then an NCC value was calculated. Here, the NCC value is 0.995, which indicates that the signal extracted from the AUX cable is almost identical to the signal extracted from the FDR. FIG. 6 illustrates signals normalized in a frequency domain and extracted from the FDR and the AUX cable. In this experiment, the signal f was normalized in the same manner as in the following Equation 5.

$${f}_{n} [ t ] = \frac{f [ t ] - u}{σ} \qquad [ Equation 5 ]$$

In Equation 5, fₙ[t] denotes a value normalized at a point in time t, u denotes mean of the signal f, and σ denotes a standard deviation of the signal f. In addition to the NCC, signal comparison was performed using a root mean square error (RMSE). The RMSE of two signals may be calculated according to the following Equation 6.

$$RMSE ( {f}_{p} , {f}_{q} ) = \sqrt{\frac{{\sum }_{t = 0}^{T} {[ {f}_{p} [ t ] - {f}_{q} [ t ] ]}^{2}}{T}} \qquad [ Equation 6 ]$$

In Equation 6, T denotes a signal length, and fₚ and f_{q} denote signals. The RMSE is calculated using normalized ENF signals extracted for 700 seconds from the FDR and the AUX cable. An RMSE value was calculated as 0.055. Standard deviations of unnormalized signals were 0.019 (FDR) and 0.072 (AUX cable), respectively.

Measurement of AUX Cable Length

To estimate power intensity according to a length of the AUX cable, a signal-to-noise ratio (SNR) of a signal around 60 Hz measured from each of a short AUX cable and a long AUX cable was measured. After converting a voltage signal to a frequency domain through FFT, the SNR was calculated as an average power ratio of signals close to 60 Hz to the power average of all frequency signals. Each voltage signal is measured for 10 seconds. In the short AUX cable experiment, the peak of the frequency domain is 0.7 Hz and the SNR is 30.67 dB. In the long AUX cable experiment, the peak is 60 Hz and the SNR is 63.73 dB. In the short AUX cable, a signal of 60 Hz was too weak to extract an ENF signal. Therefore, it can be known that an AUX cable with a sufficient length needs to be used to extract a fine and stable ENF value.

Estimation of Recording Time

In this experiment, whether an ENF signal extracted from the AUX cable is available as ground data in a forensic application is described. A typical scenario of the forensic application is to estimate a time at which a video is recorded. A video of which a recording time is to be estimated includes an ENF signal in each image frame. A video shooting time is estimated using an ENF signal collected from the AUX cable at a reference time. To create a sample target video, a video was recorded with a PowerShot SX70 HS camera and was captured at 50 frames per second (fps). A nominal frequency value of ENF is 60 Hz for Korea. The video was captured under a flashing fluorescent lamp. An ENF signal was extracted from the video. A rolling shutter refers to a process of sampling each frame of the video based on a row unit. Through this, row-by-row luminance change may be detected and the ENF signal may be extracted from the video. Pixels in each row are averaged and a frame signal is converted to a one-dimensional (1D) signal. Therefore, the entire video signals are represented in row order (r) and frame order (n), which may be expressed as R (r,n). By subtracting a time-series pixel pattern of each pixel, only a change in a light source according to a row needs to be extracted. In Equation 7, variance of a light source may be extracted by subtracting the average of R(r,n) from each frame signal R(r,n).

$$E ( r , n ) = R ( r , n ) - \ddot{R} ( r ) \qquad [ Equation 7 ]$$

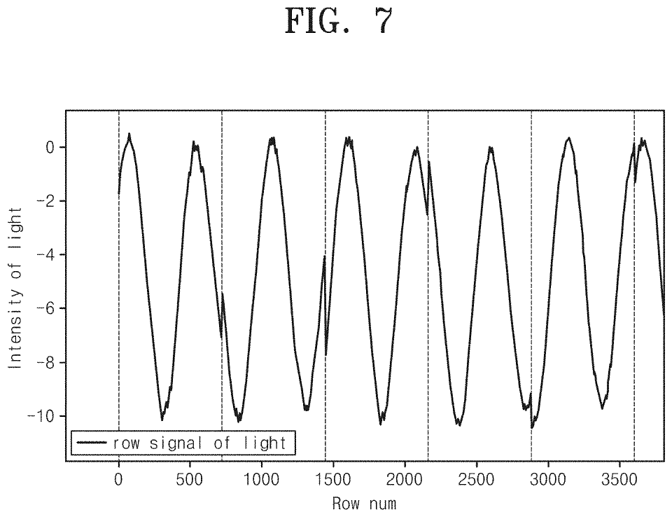

A row signal of light is called E (r; n). A camera does not receive light for a predetermined period of time until a next frame is captured. It is referred to as an idle period. During the idle period, the camera may not sample a change in light and may be unaware of a time between rows. With the assumption that the idle period is absent, it is assumed that a row signal of light is added and a time interval between rows is T=L. Here, T denotes 1/fps and L denotes a number of rows. Using QIFFT, an ENF signal may be extracted from 1-D signal by sequentially connecting the row signal of light. FIG. 7 shows a row signal of light connected in time series in a video. In FIG. 7, a dotted line (a vertical line) represents a frame change time. If a frame changes to an idle period (dotted line), it can be known that a sine wave is not smooth.

The basic assumption of the experiment is as follows. An ENF signal extracted from a video has a most similar shape to a reference signal of a test point in time at which video capture is estimated. An expected time test using an approach method of the present invention may be represented as the following Equation 8.

$${T}_{est} = {argmax}_{T} ρ ( {f}_{r} [ T \text{:} T + L \} , {f}_{v} ) \qquad [ Equation 8 ]$$

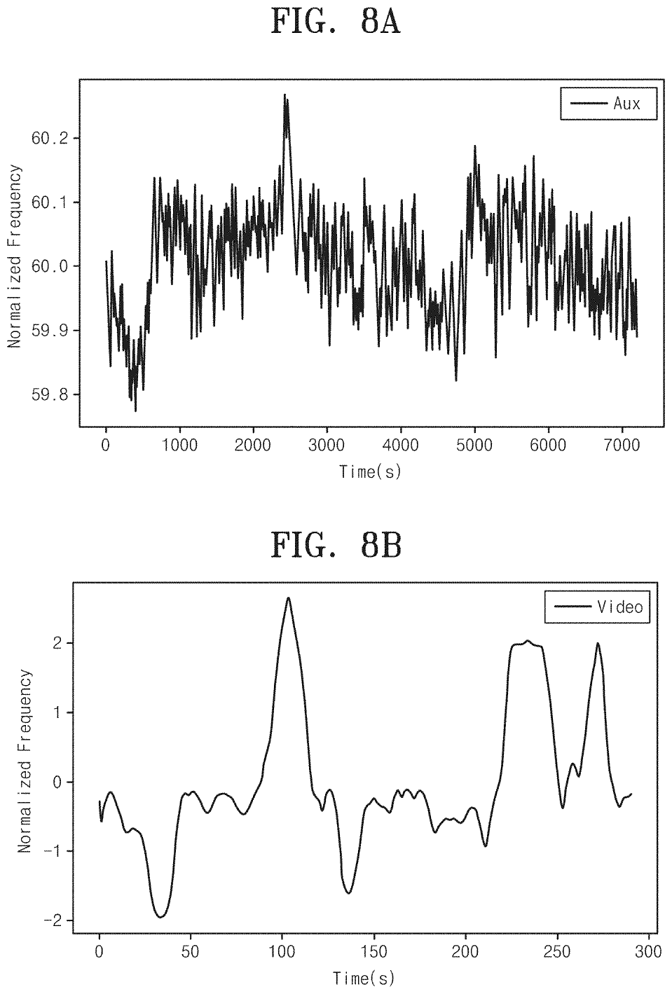

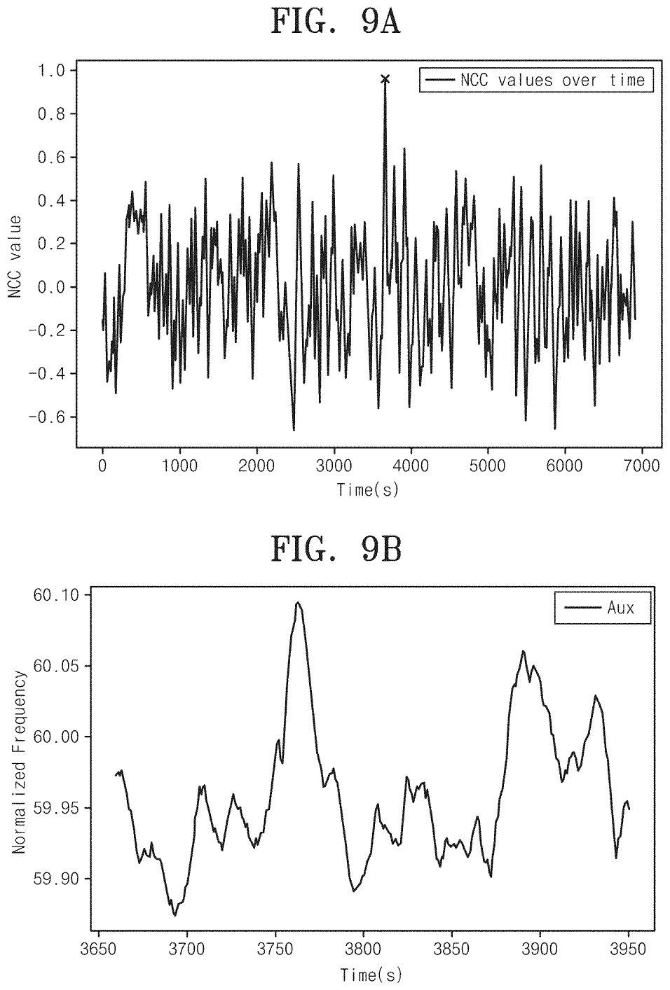

In Equation 8, fᵣ[T:t+L] denotes an interval from T to T+L of a ground truth reference ENF signal fᵣ. Here, fᵥ denotes an ENF signal extracted from the video, L denotes a length of fᵣ, and ρ denotes a function that interprets similarity between two inputs. The more similar signals, the higher a function output value. In the experiment, the similarity between the two signals were defined using NCC as ρ. FIG. 8A illustrates an ENF signal extracted from an AUX cable and FIG. 8B illustrates an ENF signal extracted from a video. FIGS. 8A and 8B show an ENF signal measured for about 3 hours through an AUX cable and an ENF signal extracted from a video captured for five minutes at a given time. FIGS. 9A and 9B illustrate NCC values over time. The NCC has a largest value at 3,650 seconds. It can be verified that a time estimated through the experiment is almost the same as when shooting the video.

In an ENF signal extraction according to an example embodiment, an electromagnetic wave generated from an AC power source may be measured only with an antenna (e.g., an electric conductor such as an AUX cable, an electric wire, a copper wire, etc.) and a fine ENF signal may be extracted from the electromagnetic wave. A spatial resolution may be improved by generating an auxiliary system that is sufficiently accurate compared to an FDR and simply installable at various positions through an ENF extraction system. Also, by using an ENF signal extracted from the AUX cable through a video recording time identification experiment, a time at which the video is captured may be known. It shows that the video may be used as ground-truth data in forensics.

Also, the aforementioned ENF measurement system or system may be implemented as a computing device that includes at least a processor and/or a memory and may also be referred to as an ENF measurement device, a measurement device, and the like. Also, the ENF measurement system may be understood as a concept that includes the aforementioned antenna and/or conversion device, for example, a sound card, an audio card, and an ADC.

Although example embodiments are described with reference to the accompanying drawings, it will be apparent to those skilled in the art to which the disclosure pertains that the technical spirit or essential features may be implemented in other specific forms without being modified. Therefore, it should be understood that the aforementioned example embodiments are illustrative in every aspect and not restrictive.

What is claimed is:

1. An electric network frequency (ENF) extraction device comprising:
an electric conductor configured to receive an electromagnetic wave generated by an adjacent alternating current (AC) power source;
a sampling device configured to sample an output signal of the electric conductor; and
a processor configured to extract ENF based on an output signal of the sampling device.

2. The ENF extraction device of claim 1, wherein the electric conductor includes an electric wire, a copper wire, an auxiliary (AUX) cable with one end cut, or an earphone with one end cut.

3. The ENF extraction device of claim 1, wherein the sampling device includes an analog-to-digital converter (ADC) configured to sample the output signal of the electric conductor by converting the output signal of the electric conductor to a digital signal, an audio card, or a sound card.

4. The ENF extraction device of claim 1, wherein the processor is configured to extract the ENF by converting the output signal of the sampling device to a frequency domain using a discrete short time Fourier transform (STFT) and by applying a quadratically interpolated fast Fourier transform (QIFFT).

5. An energy network frequency (ENF) extraction method performed by a computing device comprising at least a processor, the ENF extraction method comprising:
receiving, by an electric conductor included in the computing device, an electromagnetic wave generated by an adjacent alternating current (AC) power source;
sampling, by a sampling device included in the computing device, an output signal of the electric conductor; and
extracting, by the processor, ENF based on an output signal of the sampling device.

6. The ENF extraction method of claim 5, wherein the electric conductor includes an electric wire, a copper wire, an auxiliary cable with one end cut, or an earphone with one end cut.

7. The ENF extraction method of claim 5, wherein the sampling device includes an analog-to-digital converter (ADC) configured to sample the output signal of the electric conductor by converting the output signal of the electric conductor to a digital signal, an audio card, or a sound card.

8. The ENF extraction method of claim 5, wherein the extracting of the ENF comprises extracting the ENF by converting the output signal of the sampling device to a frequency domain using a discrete short time Fourier transform (STFT) and by applying a quadratically interpolated fast Fourier transform (QIFFT).
